(19) United States
(12) Patent Application Publication
(10) Pub. No.: US 2013/0115720 A1
(43) Pub. Date: May 9, 2013

(54) SURFACE MEASUREMENT

(71) Applicants: Arnold Allenic, Ann Arbor, MI (US); Oleh Petro Karpenko, Richmond, CA (US); Erel Milshtein, Cupertino, CA (US); Ming L. Yu, Fremont, CA (US)

(72) Inventors: Arnold Allenic, Ann Arbor, MI (US); Oleh Petro Karpenko, Richmond, CA (US); Erel Milshtein, Cupertino, CA (US); Ming L. Yu, Fremont, CA (US)

(21) Appl. No.: 13/290,673

(22) Filed: Nov. 7, 2011

(51) Int. Cl. G01N 21/55; H01L 21/66; B05C 11/00

(52) U.S. Cl. 438/7; 356/445; 118/712; 257/E21.53

(57) ABSTRACT

A method and apparatus for determining grain size of a surface. A light source is directed at the surface. Reflected light from the surface is detected. A peak surface grain wavelength is determined from the reflected light. The peak surface grain wavelength is converted to a grain size. Grain size of a semiconductor surface is used as a feedback input to control a manufacturing process.

### TECHNICAL FIELD

The present invention relates to determining grain size of a surface.

### BACKGROUND

A photovoltaic device may include a semiconductor surface having an average grain size. The average grain size of the surface can impact device performance. Therefore, it is desirable to monitor grain size during a manufacturing process to ensure that it remains within an acceptable range. Unfortunately, current techniques for measuring grain size can be destructive, expensive, and time consuming. Therefore, current techniques are not suitable for in-process analysis of surfaces.

### DESCRIPTION OF DRAWINGS

FIG. 1 is a perspective view of an apparatus including a laser and a plurality of photodetectors.

FIG. 2 is a side view of an apparatus including a laser and a plurality of photodetectors.

FIG. 3 is a plot of surface roughness wavelengths λᵣ versus photodetector signals

FIG. 4 is a comparison of peak surface grain wavelengths λᵣ_ₚₑₐₖ for two cadmium telluride semiconductor samples.

FIG. 5 is a plot of peak surface grain wavelengths λᵣ_ₚₑₐₖ versus grain sizes for thirteen semiconductor samples having a range of impurity levels.

FIG. 6 is a side view of an apparatus including a laser and a plurality of photodetectors.

FIG. 7 is a side view of an apparatus including a laser and a photodetector.

FIG. 8 is a flowchart showing steps for determining the grain size of a surface.

### DETAILED DESCRIPTION

Photovoltaic devices can include multiple layers created on a substrate (or superstrate). For example, a photovoltaic device can include a barrier layer, a transparent conductive oxide (TCO) layer, a buffer layer, and a semiconductor layer formed in a stack on a substrate. Each layer may in turn include more than one layer or film. For example, the semiconductor layer can include a first film including a semiconductor window layer, such as a cadmium sulfide layer, formed on the buffer layer and a second film including a semiconductor absorber layer, such as a cadmium telluride layer formed on the semiconductor window layer. Additionally, each layer can cover all or a portion of the device and/or all or a portion of the layer or substrate underlying the layer. For example, a “layer” can include any amount of any material that contacts all or a portion of a surface.

The semiconductor layer may be formed through a deposition process such as vapor deposition. Depending on the health of the deposition process, a variable amount of unwanted impurities may be incorporated into the semiconductor layer during the deposition process. These impurities can negatively affect the microstructure of the semiconductor layer and affect module performance. Therefore, it is desirable to avoid introducing impurities. Impurities can be avoided by including a real-time feedback process proximate to the deposition process. The feedback process may include a rapid analysis of the microstructure of the semiconductor at a post-deposition stage. The feedback process may also include adjustment of parameters of the deposition process based on the microstructure analysis.

Analysis of the microstructure can include determining an average grain size of a semiconductor surface within the module. Grain size can be important since it can have a significant impact on minority carrier recombination, intermixing, surface processing, as well as overall module performance. Therefore, it can be desirable to measure grain size of the semiconductor layer at a post-deposition stage to ensure that the deposition process is not deviating beyond predetermined specifications.

The feedback process can occur rapidly to avoid slowing of the assembly line. Preferably, the feedback process should be completed in less than about 10 seconds per module, less than about 5 seconds per module, or less than about two seconds per module. Although some methods exist for rapidly measuring surface roughness, these methods are incapable of evaluating microstructure details and, therefore, are not useful for this application. In addition, although some methods exist for measuring grain size, these methods are destructive and time consuming, so they are not appropriate for this application. Therefore, a new method for rapidly evaluating grain size within semiconductors was needed and is set forth herein.

In one aspect, a method for determining grain size of a surface can include directing a light from a light source at a surface, detecting reflected light from the surface with a plurality of photodetectors, determining a peak surface grain wavelength from the reflected light, and converting the peak surface grain wavelength to a grain size. Directing the light at the surface can include forming an angle of incidence between the light and the surface, and wherein the angle of incidence ranges from about 10 degrees to about 45 degrees. The distance between the light source and the surface can range from about 0.1 cm to about 2.0 cm. Preferably, the distance can range from about 0.2 cm to about 1.0 cm.

Detecting reflected light from the surface can include detecting light reflected at a plurality of angles of reflection from the surface. Detecting light reflecting at a plurality of angles of reflection from the surface can include detecting light reflected at a first angle of reflection ranging from about 60 degrees to about 90 degrees. Detecting light reflecting at a plurality of angles of reflection from the surface can include detecting light reflected at a second angle of reflection ranges from about 30 degrees to about 60 degrees. Detecting light reflecting at a plurality of angles of reflection from the surface can include detecting light reflected at a third angle of reflection ranges from about 0 degrees to about 30 degrees.

Determining the peak surface grain wavelength can include determining a distribution of surface grain wavelengths versus intensities for the reflected light and identifying the wavelength having the highest intensity as the peak surface grain wavelength. Converting the peak surface grain wavelength to a grain size can include providing a calibration equation describing a relationship between peak surface grain wavelength and grain size for a plurality of semiconductor surfaces having a range of impurity levels. Converting the peak surface grain wavelength to a grain size can include inputting the peak surface grain wavelength into the calibration equation and solving for grain size.

The light source can include a laser. The laser can have a wavelength ranging from about 0.4 μm to about 0.9 μm. The light source can include a light emitting diode. The plurality of photodetectors can include a photodiode. The plurality of photodetectors can include a diffraction grating. The method can include adjusting a parameter of a manufacturing process based on the grain size. The manufacturing process can include a photovoltaic module manufacturing process. The manufacturing process can include a material deposition process. The parameter adjusted can include a material deposition rate. The parameter adjusted can include a deposition temperature. The parameter adjusted can include a vaporization temperature. The parameter adjusted can include a partial pressure of an oxidizing gas in the deposition zone. The surface can include a semiconductor surface. The semiconductor surface can include cadmium telluride. The semiconductor surface can include copper indium gallium diselenide. The semiconductor surface can include cadmium sulfide.

In another aspect, an apparatus for determining grain size of a surface can include a light source configured to direct light at an incident angle relative to a substrate position and a plurality of photodetectors configured to detect reflected light from the substrate position. A peak surface grain wavelength can be determined from the detected light. The light source can include a laser. The light source can include a light emitting diode. The light source can be movably mounted to the apparatus. The plurality of photodetectors can be movably mounted to the apparatus. The laser can produce a laser beam having a wavelength ranging from about 0.4 μm to about 0.9 μm.

The plurality of photodetectors can include a first photodetector at a first angle of reflection, a second photodetector at a second angle of reflection, and a third photodetector at a third angle of reflection. The plurality of photodetectors are configured to receive scattered light originating from the laser.

The apparatus can include a computer including a calibration equation describing a relationship between a peak surface grain wavelength and grain size for a plurality of semiconductor surfaces positioned at the substrate position and having a range of impurity levels. The plurality of photodetectors can be configured to output signals to the computer upon receiving the scattered light. The computer can be configured to determine a peak surface grain wavelength from the signal. The computer can be configured to convert the peak surface grain wavelength to a grain size using the calibration equation. The computer can be configured to adjust a manufacturing process based on the grain size.

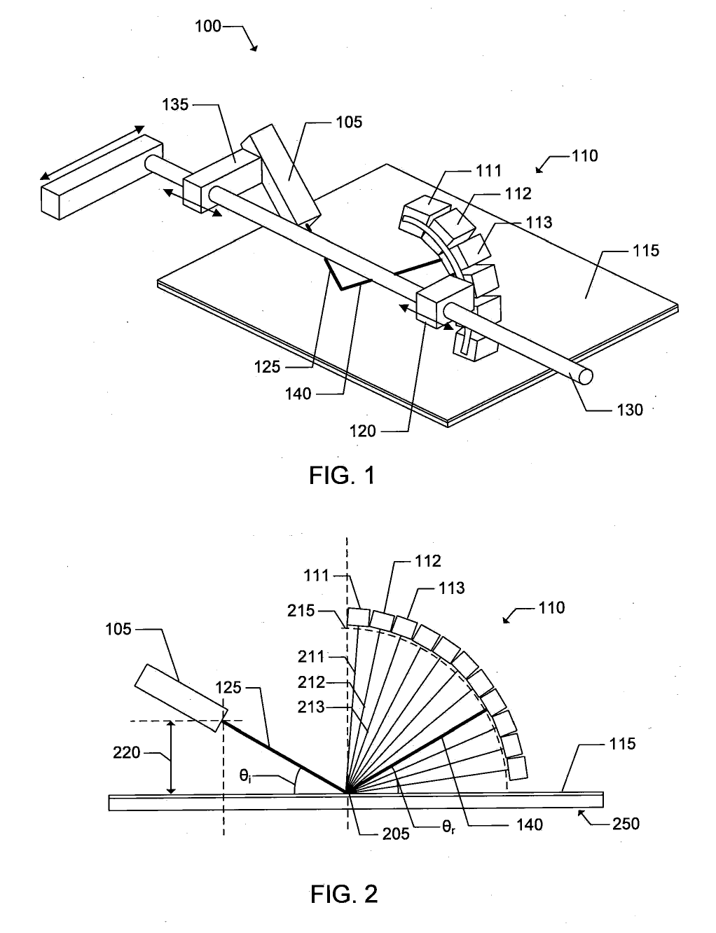

As shown by way of example in FIG. 1, an apparatus 100 for determining grain size of a semiconductor surface 115 associated with a photovoltaic module 250 may include a light source such as laser 105 and a plurality of photodetectors 110. Laser 105 may be a continuous laser or a pulsed laser. Laser 105 may produce a laser beam 125 having any suitable wavelength or range of wavelengths, for example, from about 0.4 μm to about 0.9 μm. Apparatus 100 can include any suitable light source besides (or in addition to) laser 105, including a light emitting diode capable of emitting light at any suitable wavelength or range of wavelengths.

The vertical distance 220 between the laser 105 and the surface 115 may be adjusted to capture a specific range of roughness wavelengths depending on the anticipated grain size of the semiconductor surface 115. The laser 105 may be connected to a movable mount 135 which permits the laser 105 to move relative to the semiconductor surface 115. For example, the laser may be capable of moving in 3-D space above the semiconductor surface 155, thereby allowing the laser to target multiple points across the surface of the semiconductor in rapid succession. Targeting multiple points along the surface 115 improves statistical accuracy of the grain size determination. In addition, targeting multiple points allows the apparatus 100 to assess variations in the grain size across the surface 115 caused by the deposition process. If problems with the deposition process are identified, process parameters can be adjusted to improve the process.

The plurality of photodetectors 110 may include one or more photodetectors, and the photodetectors may include any suitable devices such as, for example, photodiodes or diffiaction gratings. The plurality of photodetectors 110 may be arranged to capture light across a wide range of scattering angles as shown in FIGS. 1, 2, and 6. For example, a first photodetector 111 may be configured to capture light 211 having an angle of reflection ranging from about 60 degrees to about 90 degrees. A second photodetector 112 may be configured to capture light 212 having an angle of reflection ranging from about 30 degrees to about 60 degrees. A third photodetector 212 may be configured to capture light 210 having an angle of reflection ranging from about 0 degrees to about 30 degrees. Similarly, additional photodetectors may be arranged to capture light reflecting at predetermined angles of reflection.

The plurality of photodetectors 110 may be connected to a movable mount 120 that permits the plurality of photodetectors 110 to move relative to the semiconductor surface 115. The plurality of photodetectors 110 may move independently of the laser 105. Alternately, the plurality of photodetectors 110 may move in unison with the laser 105.

The plurality of photodetectors 110 may be arranged in any suitable configuration which allows the photodetectors to capture light reflected from the semiconductor surface 115. For example, the plurality of photodetectors 110 may be arranged along a semicircular arc 215 having a center point 205 that corresponds to a point where the laser beam 125 strikes the semiconductor surface 115. Arranging the plurality of photodetectors 110 in a semicircular arc ensures that each photodetector (e.g. 111, 112, 113) is equidistant from the center point 205. As a result, unwanted intensity variations can be avoided. To further improve signal to noise ratio, the outputs from the photodetectors can be filtered to remove noise and then amplified.

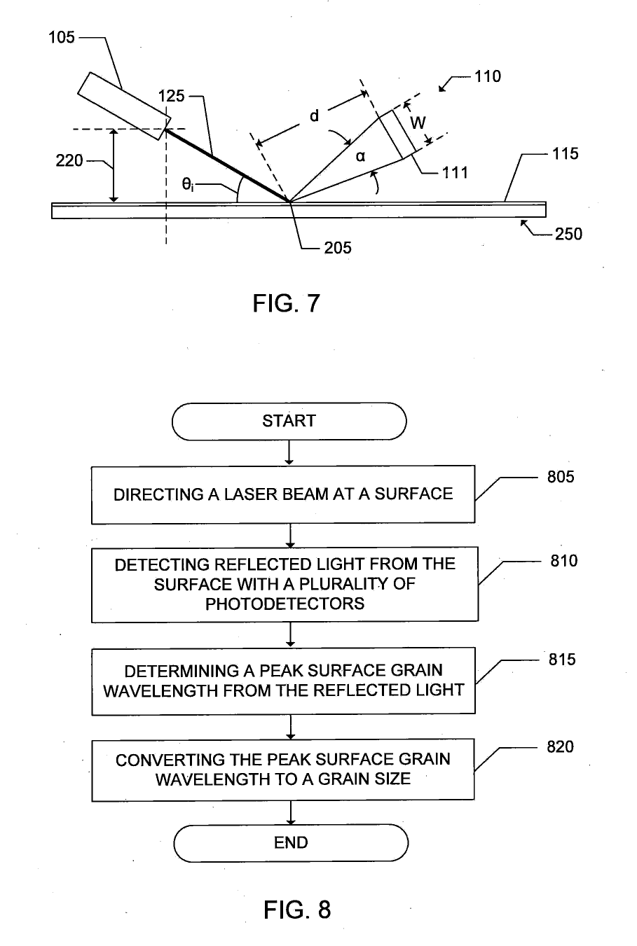

As an alternative to arranging the plurality of photodetectors in a semicircular arc, the photodetectors may be arranged in any suitable non-semicircular configuration. For example, the plurality of photodetectors may be arranged in a row, as shown in FIG. 6, where the row contains one or more photodetectors. As shown in FIG. 7, a first photodetector 111 may have a photosensitive region having a width W and may be positioned a distance d from the point 205 where the laser beam 125 strikes the semiconductor surface 115. As a result, the first photodetector 111 may collect light over a range α, as shown in FIG. 8, where α is defined as

α=2 tan⁻¹ (W/d) (Eq. 1)

Accordingly, the range of angles of reflection that the first photodetector 111 is able to detect is dependent on the width W of the detector and its distance from the point 205 where the laser beam 125 strikes the semiconductor surface 115. The detectable range of angles may be increased by moving the photodetector closer to the point 205 or by increasing the width W of the photodetector.

A partially assembled photovoltaic module containing the semiconductor surface 115 may be placed proximate to the apparatus containing a laser 105 and the plurality of photodetectors 110. The components of the apparatus 100 may move relative to the semiconductor surface 115. Alternately, the semiconductor surface may move relative to the components of the apparatus 100. For example, the module may move linearly on a conveyor, or the module may be reoriented in any suitable direction to facilitate grain size determination. Depending on manufacturing cycle times, the apparatus may determine grain sizes at several locations on the surface 115. Also, one or more apparatuses may be used to determine grain sizes at several locations the surface 115. From these determinations, a grain size profile can be determined for the surface 115.

One can apply a Fourier transform to the output signal produced by the photodetectors. In particular, the signal can be decomposed as a finite sum of sinusoidal components, each component having a single wavelength. The grain size of the semiconductor surface 115 can be determined by directing the laser beam 125 at the surface 115 and measuring the resulting reflectance distribution with the plurality of photodetectors 110. The reflectance distribution consists of a specular component 140 and diffuse component. For the specular component 140, the incident angle θᵢ is equal to the reflected angle θᵣ, where the incident angle θᵢ is the angle at which the laser beam 125 strikes the surface 115 and the reflected angle θᵣ is the angle of reflected light. For the diffuse component, the reflected angle θᵣ may include any angle except the specular angle.

Equation 2 may be used to describe the relationship between surface grain wavelength λᵣ and other variables in the process. In particular, if λ_{L} is the laser wavelength, λᵣ is the wavelength of the surface grain, and n is the diffraction order, then

sin(θᵣ)−sin(θᵢ)=n×θ_{L}/θᵣ (Eq. 2)

Specular reflectance 140 corresponds to n=0 and may be the most intense reflectance. For n=1, a distribution of surface grain wavelengths are obtained. Each surface grain wavelength can correspond to a unique diffuse reflectance angle.

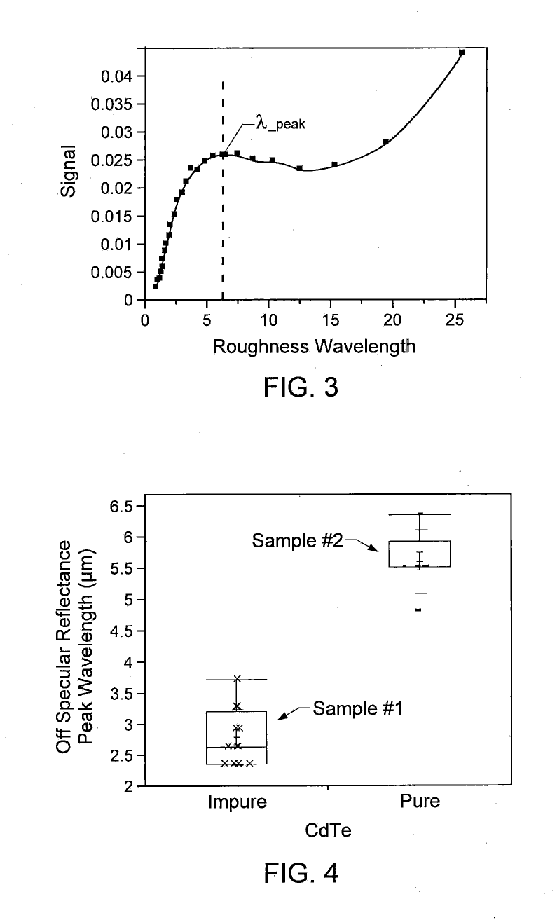

An example of a partial reflectance distribution is shown in FIG. 2 and contains a specular component 140 and several examples of diffuse components (e.g. 211, 212, 213). To analyze the diffuse spectrum, the voltage outputs of each photodetector can be combined and plotted. A typical diffuse reflectance spectrum is plotted FIG. 3. The signal intensity has a peak at λᵣ_ₚₑₐₖ.

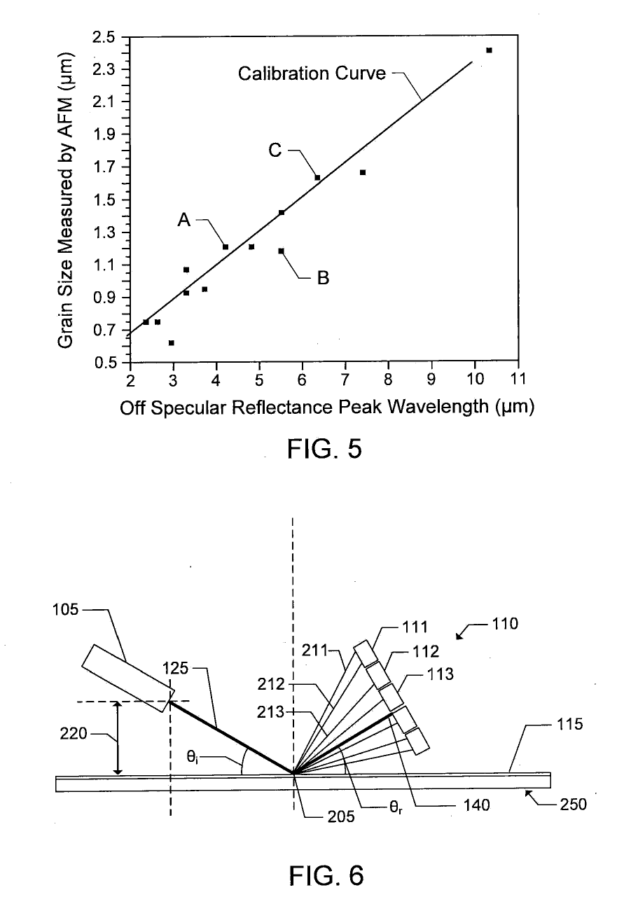

FIG. 5 demonstrates how impurity levels affect the peak surface grain wavelength λᵣ_ₚₑₐₖ of a semiconductor. In particular, FIG. 4 shows a comparison between two semiconductor samples that are identified as sample #1 and sample #2. Sample #1 is a cadmium telluride semiconductor having low purity and many impurities, whereas sample #2 is a cadmium telluride having high purity and few impurities. The peak surface grain wavelength λᵣ_ₚₑₐₖ for the sample #1 is substantially shorter than the peak surface grain wavelength λᵣ_ₚₑₐₖ for the sample #2. In general, peak wavelength will shorten as the level of impurities increases in the semiconductor.

A calibration equation may be developed to convert the peak surface grain wavelength λᵣ_ₚₑₐₖ to a grain size. The calibration equation can be developed by measuring actual grain sizes and peak surface grain wavelengths λᵣ_ₚₑₐₖ for a sample set of semiconductor surfaces having a wide range of impurity levels. For each semiconductor sample, the actual grain size can be measured using atomic force microscopy (AFM), backscattered electron diffraction, or any other suitable technique. The peak surface grain wavelength λᵣ_ₚₑₐₖ of the sample can be determined using a technique similar to the one described above. Once the data points are collected and plotted, a calibration curve can be fit to the data as shown in FIG. 5, where A, B, and C are semiconductor samples having differing levels of impurities. The calibration curve may be linear or nonlinear. The calibration curve is a graphical representation of the calibration equation used to convert a peak surface grain wavelength λᵣ_ₚₑₐₖ to a grain size.

The apparatus may include a computer and may be computer-controlled. The computer may include a graphical user interface (GUI) where a user can input data to control the process of determining a grain size. For example, the user may input parameters such as sampling frequency, laser height, laser location, laser wavelength, angle of incidence θᵢ, location of photodetectors, photodetector gain, and photodetector filter type. The user may also input the number of grain size determinations per module and location of grain size determinations per module. For instance, the user may direct the computer to conduct one or more grain size determinations for each module and may specify the location of each determination relative to the module.

Once the grain size is determined, it may be used as a feedback input to control a process associated with manufacturing photovoltaic modules. For instance, the grain size of partially assembled module may be used as feedback for a vapor deposition process. Parameters of the vapor deposition process that can be adjusted include deposition temperature, deposition rate, orifice area, conveyor speed, and melt material. For example, if the grain size is too small the process may be adjusted by increasing the partial pressure of an oxidizing gas in the deposition chamber to neutralize excess impurity sources by the vaporizing material. Alternately, the vaporization temperature may be reduced.

The signals from the plurality of photodetectors 110 may be received by the computer and may be processed by the computer. For instance, the computer may convert the signals to a set of values and determine a peak surface grain wavelength λᵣ_ₚₑₐₖ from the set of values. The computer may contain a numerical equation describing a calibration curve similar to the curve discussed above. In particular, the calibration curve may provide a relation between grain size and peak surface grain wavelength λᵣ_ₚₑₐₖ for a semiconductor surface. The equation may be used to convert the peak surface grain wavelength λᵣ_ₚₑₐₖ to a grain size. The computer may contain a variety of calibration curves for a variety of semiconductor surfaces such as, for example, cadmium telluride, cadmium stannate, cadmium sulfide, CIGS, SnO2 or any semiconductor material having a grain size greater than the laser wavelength.

Details of one or more embodiments are set forth in the accompanying drawings and description. Other features, objects, and advantages will be apparent from the description, drawings, and claims. Although a number of embodiments of the invention have been described, it will be understood that various modifications may be made without departing from the spirit and scope of the invention. Also, it should also be understood that the appended drawings are not necessarily to scale, presenting a somewhat simplified representation of various features and basic principles of the invention.

What is claimed is:

1. A method for determining grain size of a surface, the method comprising:
directing a light from a light source at a surface;
detecting reflected light from the surface with a plurality of photodetectors;
determining a peak surface grain wavelength from the reflected light; and
converting the peak surface grain wavelength to a grain size.

2. The method of claim 1, wherein directing the light at the surface comprises forming an angle of incidence between the light and the surface, and wherein the angle of incidence ranges from about 10 degrees to about 45 degrees.

3. The method of claim 1, wherein the distance between the light source and the surface ranges from about 0.2 cm to about 1.0 cm.

4. The method of claim 1, wherein detecting reflected light from the surface comprises detecting light reflected at a plurality of angles of reflection from the surface.

5. The method of claim 4, wherein detecting light reflecting at a plurality of angles of reflection from the surface comprises detecting light reflected at a first angle of reflection ranging from about 60 degrees to about 90 degrees.

6. The method of claim 4, wherein detecting light reflecting at a plurality of angles of reflection from the surface comprises detecting light reflected at a second angle of reflection ranges from about 30 degrees to about 60 degrees.

7. The method of claim 4, wherein detecting light reflecting at a plurality of angles of reflection from the surface comprises detecting light reflected at a third angle of reflection ranges from about 0 degrees to about 30 degrees.

8. The method of claim 1, wherein determining the peak surface grain wavelength comprises:
determining a distribution of surface grain wavelengths versus intensities for the reflected light; and
identifying the off-specular wavelength having the highest intensity as the peak surface grain wavelength.

9. The method of claim 1, wherein converting the peak surface grain wavelength to a grain size comprises:
providing a calibration equation describing a relationship between peak surface grain wavelength and grain size for a plurality of semiconductor surfaces having a range of impurity levels; and
inputting the peak surface grain wavelength into the calibration equation and solving for grain size.

10. The method of claim 1, wherein the light source comprises a laser.

11. The method of claim 10, wherein a laser beam emitted from the laser has a wavelength ranging from about 0.4 μm to about 0.9 μm.

12. The method of claims 1, wherein the light source comprises a light emitting diode.

13. The method of claim 1, wherein the plurality of photodetectors comprises a photodiode.

14. The method of claim 1, wherein the plurality of photodetectors comprises a diffraction grating.

15. The method of claim 1, further comprising adjusting a parameter of a manufacturing process based on the grain size.

16. The method of claim 15, wherein the manufacturing process comprises a photovoltaic module manufacturing process.

17. The method of claim 15, wherein the manufacturing process comprises a material deposition process.

18. The method of claim 17, wherein the parameter adjusted comprises a material deposition rate.

19. The method of claim 17, wherein the parameter adjusted comprises a deposition temperature.

20. The method of claim 17, wherein the parameter adjusted comprises a vaporization temperature.

21. The method of claim 17, wherein the parameter adjusted comprises a partial pressure of an oxidizing gas.

22. The method of claim 1, wherein the surface is a semiconductor surface.

23. The method of claim 22, wherein the semiconductor surface comprises cadmium telluride.

24. The method of claim 22, wherein the semiconductor surface comprises copper indium gallium diselenide.

25. An apparatus for determining grain size of a surface, the apparatus comprising:
a light source configured to direct light at an incident angle relative to a substrate position; and
a plurality of photodetectors configured to detect reflected light from the substrate position, wherein a peak surface grain wavelength can be determined from the detected light.

26. The apparatus of claim 25, wherein the light source comprises a laser.

27. The apparatus of claim 25, wherein the light source comprises a light emitting diode.

28. The apparatus of claims 25, wherein the light source is movably mounted to the apparatus.

29. The apparatus of claim 25, wherein the plurality of photodetectors are movably mounted to the apparatus.

30. The apparatus of claim 26, wherein the laser produces a laser beam having a wavelength ranging from about 0.4 μm to about 0.9 μm.

31. The apparatus of claim 25, wherein the plurality of photodetectors comprises
a first photodetector at a first angle of reflection;
a second photodetector at a second angle of reflection; and
a third photodetector at a third angle of reflection.

32. The apparatus of 26, wherein the plurality of photodetectors are configured to receive scattered light originating from the laser.

33. The apparatus of claim 25, further comprising a computer comprising a calibration equation describing a relationship between a peak surface grain wavelength and grain size for a plurality of semiconductor surfaces positioned at the substrate position and having a range of impurity levels.

34. The apparatus of claim 33, wherein the plurality of photodetectors provide is configured to output signals to the computer upon receiving the scattered light.

35. The apparatus of claim 34, wherein the computer is configured to determine a peak surface grain wavelength from the signal.

36. The apparatus of claim 35, wherein the computer is configured to convert the peak surface grain wavelength to a grain size using the calibration equation.

37. The apparatus of claim 36, wherein the computer is configured to adjust a manufacturing process based on the grain size.
